(19) United States
(12) Patent Application Publication
(10) Pub. No.: US 2005/0104180 A1
(43) Pub. Date: May 19, 2005

(54) Electronic device with reduced entrapment of material between die and substrate electrical connections

(76) Inventors: Vassoudevane Lebonheur, Tempe, AZ (US); Terrence Caskey, Phoenix, AZ (US)

Correspondence Address: EITAN, PEARL, LATZER & COHEN ZEDEK LLP, 10 ROCKEFELLER PLAZA, SUITE 1001, NEW YORK, NY, 10020, US

(21) Appl. No.: 10/706,963

(22) Filed: Nov. 14, 2003

(51) Int. Cl. H01L 23/48

(52) U.S. Cl. 257/686; 257/778

(57) ABSTRACT

A semiconductor package where electrical connections or bumps extending from the die may have, for example, at least a distal portion of the die where the electrical connection or bump narrows when moving towards the distal tip, and/or where a connection point or area on the bump or electrical connection that is attached to the die is wider than a more distal connection point on the bump electrical connection, or other suitable geometry.

### BACKGROUND OF TEE INVENTION

In semiconductor packaging a semiconductor die may be connected electrically to a package carrier or section of a carrier such as, for example, a substrate. The package carrier may provide electrical connections from the die to the exterior of the package. The die and package carrier may be connected via connection structures such as, for example, “bumps,” balls or other relatively solid masses of electrical connection material. Bumps may be, for example, 15-100 μm high, and 50-150 μm in diameter. Other dimensions are possible. Such bumps may be contrasted with longer and more flexible wires. One current shape for bumps on a die includes a relatively flat bottom where the size or area of the end furthest from the die is substantially similar to the size or area or the end attached to the die. For example, a cylindrical shape may be used.

Connection structures may be formed from, for example, lead-tin and lead-free solders, or other materials. Such connection structures may be formed by, for example, thin film deposition and etching operations, paste-deposition and electroplating.

During manufacture, a fill substance or underfill (such as, for example, no-flow underfill (“NUF”) may be added between the die and the substrate. Underfill may include, for example, epoxy or other substance that fills the area between the die and the substrate or carrier, surrounding the bumps. Such substances may perform functions such as, for example, controlling the stress in the joints between the die bumps and substrate bumps caused by the difference in thermal expansion between the silicon die and the substrate, providing structural support to the overall package, and connecting the die and substrate. The underfill or other fill substance may absorb the stress, reducing the strain on the bumps, increasing the life of the finished package.

Fill substance such as, for example, underfill and fillers, may get entrapped in the joints between the die bumps and substrate bumps or otherwise contaminate or interfere with the joints during manufacture. During the process of forming the joint, solder which may form part of a die or substrate bump may melt, and fill substance may enter the molten solder.

### BRIEF DESCRIPTION OF THE DRAWINGS

The subject matter regarded as the invention is particularly pointed out and distinctly claimed in the concluding portion of the specification. The invention, however, both as to organization and method of operation, together with features and advantages thereof, may best be understood by reference to the following detailed description when read with the accompanied drawings in which:

FIG. 1A is a cutaway view of a chip package according to one embodiment of the present invention;

FIG. 1B is a schematic view of a chip package according to one embodiment of the present invention;

FIG. 1C is a schematic view of a chip package according to one embodiment of the present invention;

FIG. 2 is a schematic diagram of the assembly of a package according to one embodiment of the invention;

FIG. 3 is a schematic diagram of the assembly of a package according to one embodiment of the invention;

FIG. 4 depicts a non-limiting set of electrical contacts or bumps that may be connected to a die in accordance with embodiments of the present invention;

FIG. 5 depicts a set of sample electrical contacts or bumps in perspective view in accordance with embodiments of the present invention; and

FIG. 6 is a schematic diagram of a computer system according to one embodiment of the system and method of the present invention.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION OF TH INVENTION

In the following detailed description, numerous specific details are set forth in order to provide a thorough understanding of the invention. However, it will be understood by those of ordinary skill in the art that the invention may be practiced without these specific details. In other instances, well-known methods, procedures, components, units and/or circuits have not been described in detail so as not to obscure the invention.

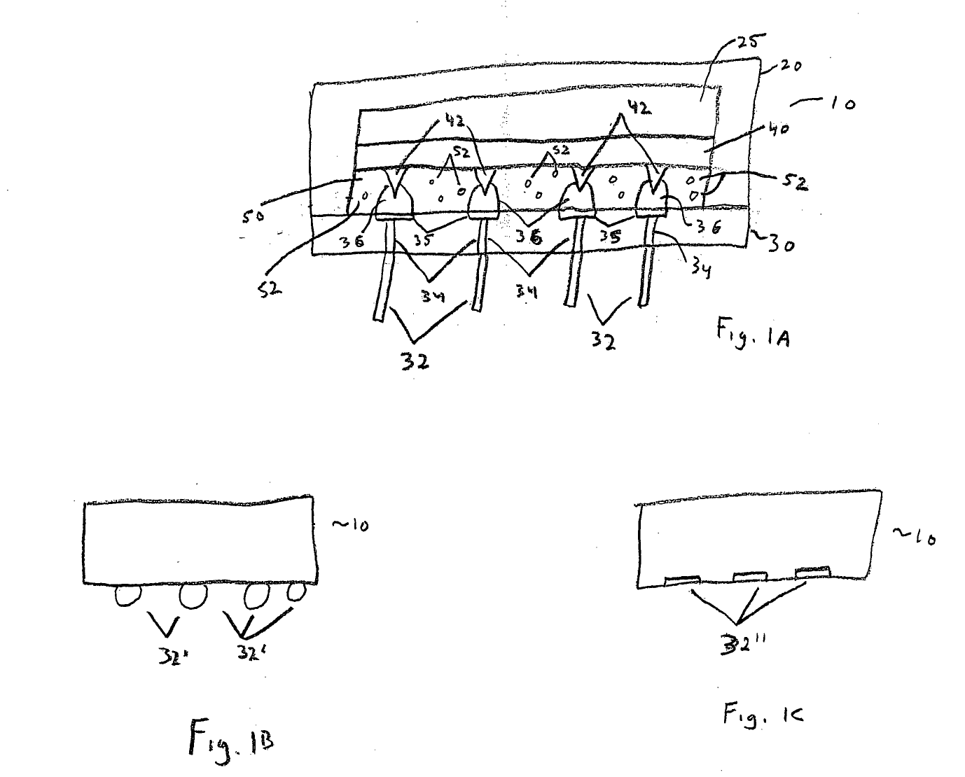

FIG. 1A is a cutaway view of a chip package according to one embodiment of the present invention. Referring to FIG. 1A, package 10 includes a heat spreader 20, an electrical unit such as, for example, a substrate 30, and an electrical unit such as, for example, a die 40, which may be a semiconductor die. A material or structure such as thermal interface material 25 may be placed between heat spreader 20 and die 40. Die 40 may be, for example, a processing, memory or other electronic chip or device. Thermal interface material 25 and heat spreader 20 need not be used. Substrate 30 may provide structural strength for the package 10, and provide external electrical connections for die 40. Substrate 30 may include external electrical connections such as for example, pins 32, providing external electrical connections. For example, pins 32 may connect to sockets in a circuit board. Connections other than pins may be used. Pins 30 connect to internal electrical connections 34 inside substrate 30 which in turn connect to electrical contacts or bumps 36, possibly via pads or other electrical connections 35 on the surface of substrate 30. Combinations of components such as, for example, pins 30, internal electrical connections 34, pads or other electrical connections 35 and bumps 36 may be formed from one piece of material. Furthermore, other systems and structures for forming electrical connections on a substrate, or support device in a package may be used. While a certain number of pins and bumps are shown in FIG. 1A, other numbers may be used. Bumps 36 may have other shapes and structures. Other structures or components, such as sealant, may be used.

Die 40 may include one or more electrical contacts or bumps 42, which provide electrical connections to a structure external to the die such as, for example, substrate 30. Bumps 42 may extend from die 40 and may carry electrical signals (such as, for example, data, control and/or power signals) and may contact bumps 36. Thus electrical signals may pass between the die 40 and the pins 32 via bumps 42, bumps 36, pads 35 and electrical connections 34. In an alternate embodiments electrical contacts or bumps 42 located on a die may connect with structures on a substrate other than bumps, such as, for example, pads. Further, a die including bumps or other connections according to embodiments of the present invention need not be contained within a package having a heat spreader and substrate, and need not be contained within a package having a heat spreader and substrate as shown or arranged in the configuration as shown. For example, a die may electrically connect with connectors above or above and below the die, or to the side of the die, depending on the orientation of the die and other components.

While in FIG. 1A die 40 includes a certain set of electrical contacts or bumps, and substrate 30 includes a second set of electrical contacts or bumps, in some embodiments the configuration or structure of the sets may be reversed. For example, an electrical unit such as, for example, a substrate may include bumps that are described elsewhere herein as extending from a die, and an electrical unit such as, for example, a die may include bumps that are described elsewhere herein as extending from a substrate. Furthermore, both a die and a substrate may include bumps or electrical connections that are described herein as extending from a die.

The substrate 30 may be constructed of, for example, ceramic materials or organic materials; other suitable materials may be used. Heat spreader 20 may include metal such as copper; other suitable materials may be used. Bumps 36 may include, for example, solder such as, for example, tin-lead solder or lead free solder including, for example, tin and/or silver, a tin-silver alloy, a tin-copper alloy, etc. and may be manufactured using, for example, a solder reflow process. Bumps 36 or other electrical contacts attached to substrate 30 may include other suitable substances and may be made using other manufacturing methods and materials, such as, for example, using conductive adhesive. Bumps 36 need not include solder or substances that melt during the manufacturing of the package; for example, bumps 36 may be formed from a high percentage copper material.

Bumps 42 may be, for example, copper, but other suitable substances may be used. In one embodiment bumps 42 may be primarily copper or include at least 50% copper. In another embodiment bumps 42 may include at least 80% copper; other suitable proportions may be used. In one embodiment, bumps 42 do not melt at the temperatures used during manufacturing of the package 10, and bumps 36 do; however, in other embodiments, substances may be used for bumps 36 and bumps 42 that cause bumps 36 and/or bumps 42 to remain solid or to melt during manufacture of the package 10. For example, bumps 42 may remain solid at temperatures below approximately 400 degrees Celsius. In one embodiment, the package 10 is manufactured at between approximately 200 and 300 degrees Celsius. Other temperature ranges and limits may be used and, furthermore, high heat need not be used during manufacture. Bumps 42 may be manufactured and attached to die 40 via known methods, such as, for example, plating; other manufacturing methods may be used.

Package 10 includes material 50, such as, for example, an NUF material. In one embodiment material 50 is not electrically conductive. Material 50 may include, for example, epoxy resins. Other suitable materials may be used. Material 50 may include additional fillers 52 such as, for example, silica or silica fibers, glass, etc.

FIGS. 1B and 1C show alternate configurations for external connections of a package according to embodiments of the present invention. Some components in FIG. 1A are not shown in FIGS. 1B and 1C for clarity. Referring to FIG. 1B a package 10 includes balls 32′, providing electrical connections between package 10 and other components. In one embodiment, balls 32′ are included within a ball grid array (BGA) package. Referring to FIG. 1C a package 10 includes electrical connections 32″, providing electrical connections between package 10 and other components. In one-embodiment, electrical connections 32″ are included within a land grid array (LGA) package. Other types of packages and connections may be used.

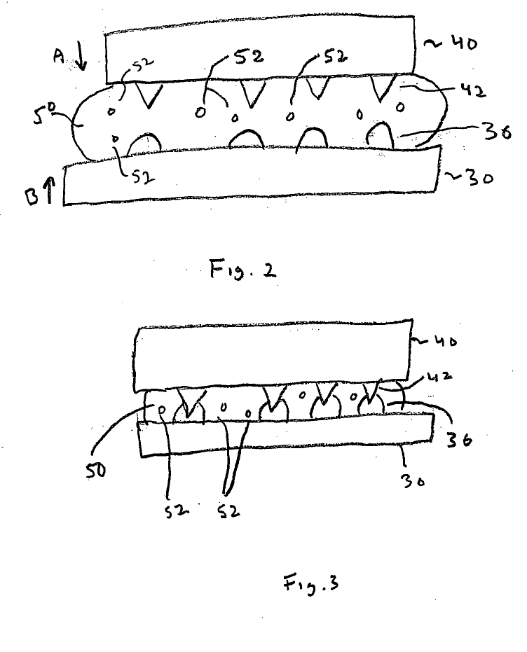

FIG. 2 is a schematic diagram of the assembly of a package according to one embodiment of the invention. Some components in FIG. 1A are not shown in FIG. 2 for clarity. The package assembly depicted in FIG. 2 is exemplary; other assembly methods may be used. Referring to FIG. 2, during assembly, material 50 is inserted or otherwise placed between substrate 30 and die 40. Substrate 30 and die 40 are pressed together, per the arrows A and B. The assembly may be under high heat such that bumps 36 are molten during the process. Bumps 42 contact bumps 36. Bumps 42 may enter the molten material included in bumps 36, and/or, depending on bump geometry and other factors the molten material included in bumps 36 may, via, for example, capillary action, climb the sides of or surround bumps 42.

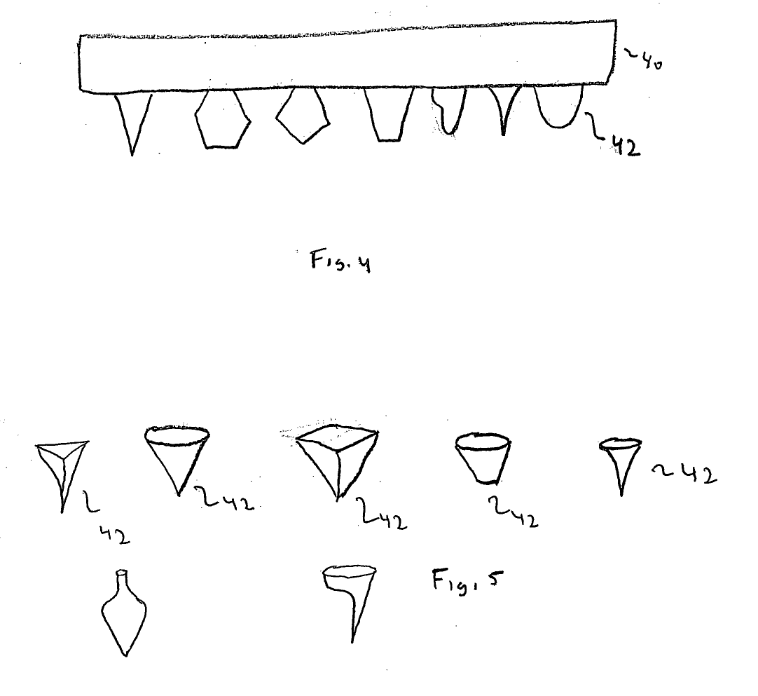

FIG. 3 is a schematic diagram of the assembly of a package according to one embodiment of the invention. Some components in FIG. 1A are not shown in FIG. 2 for clarity. Referring to FIG. 3, after substrate 30 and die 40 are pressed together, bumps 42 are in contact with bumps 36. A minimal amount or none of material 50 is caught or trapped between bumps 42 and bumps 36. The shape of bumps 42 may help prevent material 50 from being caught or trapped between bumps 42 and bumps 36. Other configurations for the joint or contact between bumps 42 and bumps 36 may be used.

Bumps 42 or electrical connections on the die 40 may be shaped, for example, such that a portion of the bump that is distal to the die is narrower or has a smaller side cross section than the portion of the bump that is connected to or closer to the die. The electrical connections or bumps 42 may include a distal tip and a base, wherein at least a distal portion of the electrical connection narrows towards the distal tip, or is narrower than at least a portion closer to the base. The side cross section of the bump for the purposes of this discussion is the cross section when viewed from a side of the bump. In one embodiment, the bumps 42 include a first end connection area connected to the die and are wider than a second end connection area further from the die. The size or area of the end furthest from the die need not be smaller than that of the end attached to the die, and along a portion of the electrical connections the width may increase with the distance from the die, but the overall shape of the bump may be such that a narrowing occurs when moving away from the die; such narrowing may start a certain distance from the die. In some embodiments, the shape of the bumps on the die may help minimize the contact area between the die bumps and substrate bumps.

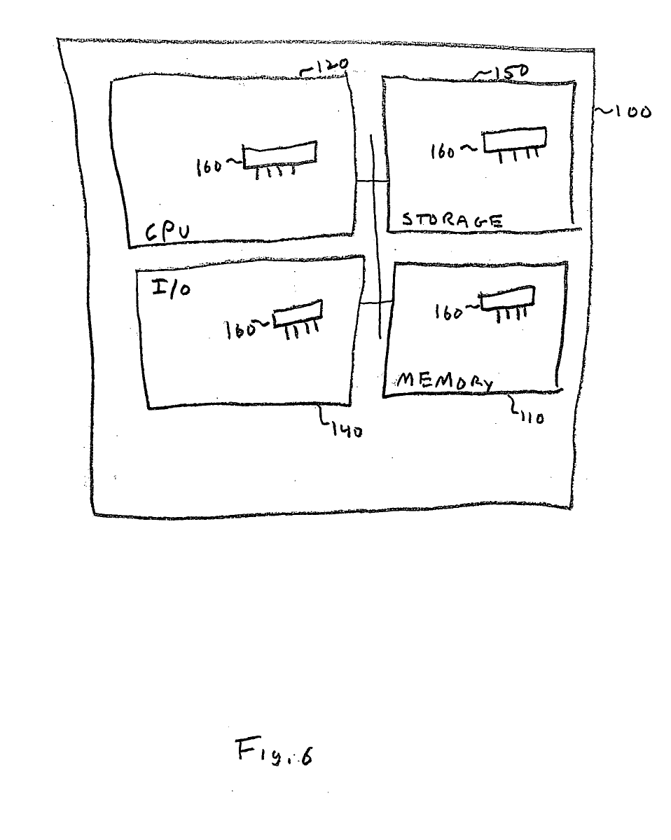

Various suitable shapes, cross sections and side cross sections may be used. FIG. 4 depicts a non-limiting set of electrical contacts or bumps that may be connected to a die in accordance with embodiments of the present invention. Referring to FIG. 4, the side cross section of the bumps 42 may be, for example, triangular, hexagonal, pentagonal, or other suitable shapes. The shape may be, for example, that of a frustum or conical frustum, or a portion of a sphere, ellipse or other rounded shape. A relatively flat bottom may be included. Other suitable shapes may be used. A shape where the bump is tapered towards the distal end may be used, and also a shape where the bump includes a distal tip and a base, the distal tip being narrower than the base, may be used. FIG. 5 depicts a set of sample electrical contacts or bumps in perspective view in accordance with embodiments of the present invention. Referring to FIG. 5, while bumps used in some embodiments are symmetrical when viewed axially, such symmetry need not be used. Furthermore, symmetry in the side cross section need not be used.

The amount and rate of narrowing may vary—for example, with a triangular side cross section as shown in FIG. 4, a regular, continuous narrowing may be used, but if a “golf-tee” or rounded shape is used, the rate may not be regular. The bumps or electrical connections need not be symmetrical, and different bumps of different sizes and shapes may be used on one die. In one embodiment, the bumps 42 are approximately 15-150 microns wide at their widest or 15-150 microns in diameter at their widest and are approximately 15-150 microns long; other dimensions may be used.

In one embodiment, one set of contacts or bumps, such as, for example, die bumps 42, may include a material that remains substantially solid during manufacture and thus does not lose its shape, such as, for example, copper or a suitable copper alloy. The electrical contacts or bumps may be shaped to lower or minimize the amount of entrapment of foreign substances, such as, for example, material 50, in the electrical contacts between the die 40 and another unit such as, for example, substrate 30. That at least one set of bumps does not lose its shape during manufacture, in combination with having a certain shape, may aid in reducing material entrapment. For example, die bumps 42, if manufactured with a certain shape, may be able to push or deflect material 50 out of the path of the bumps 42 and 36 converging during package manufacturing.

Further, the shape or profile of the bumps may lower drag on material such as, for example, resin and filler as this material is removed or squeezed out of the space between the die and substrate during manufacture. A narrow or streamlined profile or shape on at least one set of bumps may cause less drag on material moving in a direction generally parallel with the die and substrate. The shape or profile of the bumps may allow for a more effective joint between die bumps or electrical connections and substrate bumps or electrical connections. For example, with some geometries, such as, for example, a conical or triangular side cross section geometry, the molten bump substance on the substrate may climb along the die bump as the die bump enters or contacts the substrate bump due to, for example, capillary action.

Bumps, connection structures, or electrical contacts according to embodiments of the present invention may be manufactured according to known manufacturing methods. For example, plating or chemical plating such as electrodeposition may be used. In one embodiment, photoresist geometry can be controlled by lithography process optimization, resulting in a desired shape for bumps, connection structures, or electrical contacts. The shape of the photoresist geometry may form the shape of the bumps, connection structures, or electrical contacts. In the case of more complex geometries, such as one where a bump starts with a relatively narrow geometry close to the die, widens, and then becomes narrower when distal to the die, a multi-stage process, such as a multi-stage lithography process, may be used. For example, in a first stage one section, such as a section that widens as it gets further from the die, may be formed, and then in a second stage, another section that narrows as it gets further from the die may be formed. In a further embodiment a process such as sputter etching may be used to shape bumps, connection structures, or electrical contacts. For example, a bump with a rectangular cross section can be shaped by bombardment with an inert gas such as, for example, argon, in one or more directions. Material may be removed from the bump to form a bump of suitable shape. Other suitable manufacturing methods and systems may be used.

Die 40 may be, for example, a processing, memory or other electronic chip including electronic components such as, for example, transistors, and may be fabricated using, for example, silicon and other substances. Die 40 may include the functionality of, for example, processing, calculating, I/O operations, memory or data storage, the detection of substances, electromagnetic radiation or other phenomenon, etc. For example die 40 may form part of a processor, central processing unit (CPU), memory, I/O unit, detector, transmitter, signal processor, math co-processor, etc. Die 40 may perform other fi ctions or be part of other units. More than one die may be included in a package.

FIG. 6 is a schematic diagram of a computer system according to one embodiment of the system and method of the present invention. Referring to FIG. 6, computer system 100 includes one or more memories 110, such as, for example, random access memories (AMs), dynamic random access memories (DRAMs), read only memories (ROMs), or other memories, one or more processors 120, such as, for example, CPUs or other processors, and other units such as, for example, one or more input/output (I/O) units 140, one or more mass storage units 150 such as, for example, hard disk drives, compact disk drives, floppy disk drives, or other units, and possibly other units. One or more of the units 110, 120, 140, 150 may include chips or other integrated and/or packaged devices 160. Such devices 160 may be include structures similar to those described herein, for example die bumps or electrical connections shaped in a manner described herein. Such devices 160 may perform various functions, as is known in the art for packaged devices or integrated circuits, such as, for example, processing, calculating, I/O, storage, detecting, etc.

While certain features of the invention have been illustrated and described herein, many modifications, substitutions, changes, and/or equivalents may occur to those skilled in the art. It is, therefore, to be understood that the appended claims are intended to cover all such modifications and/or changes.

1. A device comprising:
a first electrical unit;
a second electrical unit; and
a first set of electrical connections extending from the second electrical unit, each of the first set of electrical connections including a distal tip and a base, wherein at least a distal portion of each of the first set of electrical connection narrows towards the distal tip, each of the first set of electrical connections including at least 50% copper.

2. The device of claim 1, wherein the first electrical unit is a substrate and the second electrical unit is a semiconductor die.

3. The device of claim 1, wherein the first electrical unit is a semiconductor die.

4. The device of claim 1 wherein each of the first set of electrical connections includes at least 80% copper.

5. The device of claim 1, wherein each of the first set of electrical connections has a melting point of at least 400 degrees Celsius.

6. The device of claim 1, wherein each of the first set of electrical connections is tapered.

7. The device of claim 1, wherein along a portion of the first set of electrical connections the width increases with the distance from the die.

8. The device of claim 1, wherein each of the first set of electrical connections has a triangular or substantially triangular side cross section.

9. The device of claim 1, wherein each of the first set of electrical connections has a conical or substantially conical shape.

10. The device of claim 1, wherein each of the first set of electrical connections has a pentagonal or substantially pentagonal side cross section.

11. The device of claim 1, wherein each of the first set of electrical connections has a shape of a frustum or has a substantially frustum-like shape.

12. The device of claim 1, comprising a non-conductive material disposed between the first electrical unit and the second electrical unit.

13. The device of claim 1, comprising a first set of electrical connections extending from the first electrical unit and connecting with the second set of connections.

14. A device comprising:
a substrate including substrate electrical connections; and
a semiconductor die including set of die electrical connections, each of the die electrical connections having a first end connection area and a second end connection area, the first end connection area being connected to the semiconductor die, the first end connection area being wider than the second end connection area.

15. The device of claim 14, wherein each of the die electrical connections includes at least 50% copper.

16. The device of claim 14, wherein each of the die electrical connections has a triangular or substantially triangular side cross section.

17. The device of claim 14, wherein each of the die electrical connections has a conical or substantially conical shape.

18. The device of claim 14, comprising a non-conductive material disposed between the semiconductor die and the substrate.

19. A device comprising:
a substrate;
a semiconductor die; and
a set of die electrical connections extending from the semiconductor die, each of the die electrical connections including a distal tip and a base, wherein the distal tip is narrower than a portion closer to the base, wherein each of the die electrical connections includes at least 50% copper.

20. The device of claim 19 wherein each of the die electrical connections includes at least 80% copper.

21. The device of claim 19, wherein each of the die electrical connections has a melting point of at least 400 degrees Celsius.

22. The device of claim 19, wherein each of the die electrical connections is tapered.

23. The device of claim 19, wherein each of the die electrical connections has a triangular or substantially triangular side cross section.

24. The device of claim 19, wherein each of the die electrical connections has the shape of a frustum or has a substantially frustum-like shape.

25. The device of claim 19, comprising a non-conductive material disposed between the semiconductor-die and the substrate.

26. The device of claim 19, comprising substrate electrical connections extending from the substrate and connecting with the die electrical connections.

27. A device comprising:
a processor, the processor including:
a substrate;
a semiconductor die; and
a set of electrical connections extending from the semiconductor die, each of the electrical connections including a distal tip and a base, wherein the distal tip is narrower than the base, wherein each of the electrical connections includes at least 50% copper; and
a DRAM.

28. The device of claim 27, wherein each of the electrical connections includes at least 80% copper.

29. The device of claim 27, comprising a non-conductive material disposed between the semiconductor die and the substrate.
